(19) United States
(12) Patent Application Publication
(10) Pub. No.: US 2023/0324322 A1
(43) Pub. Date: Oct. 12, 2023

(54) Sensors For Contaminants

(71) Applicant: 3M INNOVATIVE PROPERTIES COMPANY, St. Paul, MN (US)

(72) Inventors: Phillip E. Tuma, Faribault, MN (US); Steven Y. Yu, St. Paul, MN (US)

(21) Appl. No.: 18/042,317

(22) PCT Filed: Sep. 15, 2021
(86) PCT No.: PCT/IB2021/058435

§ 371 Date: Feb. 21, 2023

Related U.S. Application Data
(60) Provisional application No. 62/706,932, filed on Sep. 18, 2020.

(51) Int. Cl. G01N 27/22; H05K 7/20

(52) U.S. Cl. CPC G01N 27/22; H05K 7/20818; H05K 7/203

(57) ABSTRACT

A thermal management system includes a housing having an interior space; a heat-generating component disposed within the interior space; a working fluid disposed within the interior space such that the heat-generating component contacts a liquid phase of the working fluid; and a sensing mechanism configured to detect the presence of one or more organic contaminants in the working fluid at concentrations of 100 ppm or less.

### FIELD

The present disclosure relates to sensors and systems and methods for sensing contaminants in fluid immersion thermal management systems.

### BRIEF DESCRIPTION OF THE FIGURES

FIG. 1 is a schematic illustration of a two-phase immersion cooling system according to some embodiments of the present invention.

FIG. 2 is a schematic illustration of a sensing mechanism in accordance with some embodiments of the present disclosure.

FIG. 3 is a schematic illustration of a sensing mechanism in accordance with some embodiments of the present disclosure.

### DETAILED DESCRIPTION

Large scale computer server systems can perform significant workloads and generate a large amount of heat during their operation. A significant portion of the heat is generated by the operation of the server systems. Due in part to the large amount of heat generated, these servers are typically rack mounted and air-cooled via internal fans and/or fans attached to the back of the rack or elsewhere within the server ecosystem. As the need for access to greater and greater processing and storage resources continues to expand, the density of server systems (i.e., the amount of processing power and/or storage placed on a single server, the number of servers placed in a single rack, and/or the number of servers and or racks deployed on a single server farm), continue to increase. With the desire for increasing processing or storage density in these server systems, the thermal challenges that result remain a significant obstacle. Conventional cooling systems (e.g., fan based) require large amounts of power, and the cost of power required to drive such systems increases exponentially with the increase in server densities. Consequently, there exists a need for efficient, low power usage systems for cooling the servers, while allowing for the desired increased processing and/or storage densities of the server systems.

Two-phase immersion cooling is an emerging cooling technology for the high-performance server computing market which relies on the heat absorbed in the process of vaporizing a liquid (the cooling fluid) to a gas (i.e., the heat of vaporization). The working fluids used in this application must meet certain requirements to be viable in the application. For example, the boiling temperature during operation should be in a range between for example 30° C.-75° C. Generally, this range accommodates maintaining the server components at a sufficiently cool temperature while allowing heat to be dissipated efficiently to an ultimate heat sink (e.g., outside air). The working fluid must be inert so that it is compatible with the materials of construction and the electrical components. Certain perfluorinated and partially fluorinated materials meet these requirements.

In a typical two-phase immersion cooling system, servers are submerged in a bath of working fluid (having a boiling temperature Tb) that is sealed and maintained at or near atmospheric pressure. A vapor condenser integrated into the tank is cooled by water at temperature T_{w}. During operation, after steady reflux is established, the working fluid vapor generated by the boiling working fluid forms a discrete vapor level as it is condensed back into the liquid state. Above this layer is the “headspace,” a mixture of a non-condensable gas (typically air), water vapor, and the working fluid vapor which is at a temperature somewhere between T_{w} and the temperature of ambient air outside the tank, T_{amb}. These 3 distinct phases (liquid, vapor, and headspace) occupy volumes within the tank.

During normal operation of immersion cooling systems, fluorochemical working fluids will extract, for example, hydrocarbon contaminants from various components within the tank such as elastomeric polymers such as adhesives, coatings, thermal compounds and PVC insulation. The solubility of these contaminants varies. For example, dioctylpthalate (DOP), a common PVC plasticizer is soluble in perfluorocarbon (PFC) fluids at part per million (ppm) levels but is fully miscible in certain hydrofluoroethers. High molecular weight “tars” have far lower solubility. Regardless of solubility, in real world applications, these contaminants are typically present only at very low concentrations on the order of 100 ppm or less, concentrations that may not even be quantifiable with sophisticated analytical instruments such as GM/MS and H-NMR.

Even at these very low concentrations, thermal performance of the system can be significantly impacted. For example, consider that a 200-Watt microprocessor can boil approximately 100 liters of thermal management fluid per day. If that fluid contains only 10 ppm of the contaminant DOP, then it contains 1-2 g of DOP. As that 100 liters boils away, some of the nonvolatile DOP is left behind by distillation and will precipitate onto and coat the boiling surface of the electronic device (e.g, microprocessor), thereby impeding heat transfer. As will be discussed in further detail in the Examples, performance of the electronic device (e.g., the operating junction temperature of the microprocessor) degrades immediately upon addition even very low amounts of certain contaminants, including DOP.

Consequently, systems or apparatus for measuring, in situ, the level of certain contaminants in the thermal management fluid so that preventive action (e.g., changing a filter) can be taken before performance is affected or hardware is damaged, are desirable.

As used herein, “fluoro-” (for example, in reference to a group or moiety, such as in the case of “fluoroalkylene” or “fluoroalkyl” or “fluorocarbon”) or “fluorinated” means (i) partially fluorinated such that there is at least one carbon-bonded hydrogen atom, or (ii) perfluorinated.

As used herein, “perfluoro-” (for example, in reference to a group or moiety, such as in the case of “perfluoroalkylene” or “perfluoroalkyl” or “perfluorocarbon”) or “perfluorinated” means completely fluorinated such that, except as may be otherwise indicated, any carbon-bonded hydrogens are replaced by fluorine atoms.

As used herein, “halogenated material” means an organic compound that is at least partially halogenated (up to completely halogenated) such that there is at least one carbon-bonded halogen atom.

As used herein, “selective removal” refers to at least partial removal (up to total removal) of one or more particular fluid components (but less than all fluid components) from a sealed volume that includes two or more fluid components.

As used herein, “fluid” refers to the liquid phase and/or the vapor phase.

As used herein, the singular forms “a”, “an”, and “the” include plural referents unless the content clearly dictates otherwise. As used in this specification and the appended embodiments, the term “or” is generally employed in its sense including “and/or” unless the content clearly dictates otherwise.

As used herein, the recitation of numerical ranges by endpoints includes all numbers subsumed within that range (e.g. 1 to 5 includes 1, 1.5, 2, 2.75, 3, 3.8, 4, and 5).

Unless otherwise indicated, all numbers expressing quantities or ingredients, measurement of properties and so forth used in the specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

Generally, the present disclosure is directed to immersion cooling systems that allow for continuous, in situ monitoring of the concentration of certain contaminants in the thermal management fluid.

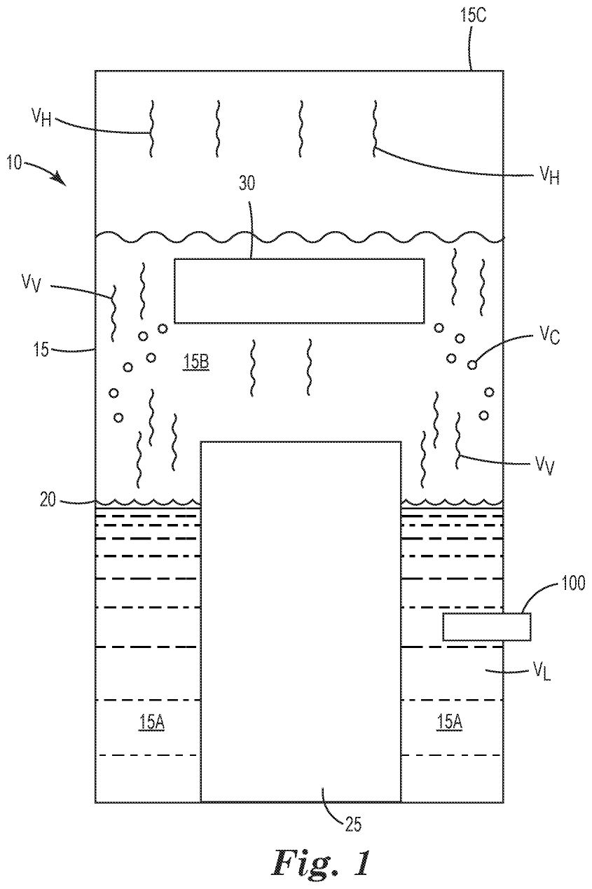

Referring now to FIG. 1, in some embodiments, a two-phase immersion cooling system 10 may include a housing 15 having an interior space. Within a lower volume 15A of the interior space, a liquid phase V_{L} of a working fluid having an upper liquid surface 20 (i.e., the topmost level of the liquid phase V_{L}) may be disposed. The interior space may also include an upper volume 15B extending from the liquid surface 20 to an upper wall 15C of the housing 15. During steady state operation of the system 10, the upper volume 15B may include a vapor phase V_{V} of the working liquid (generated by the boiling working fluid and forming a discrete phase as it is condensed back into the liquid state) and a headspace phase V_{H} including a mixture of non-condensable gas (e.g., air) and working fluid vapor, which is disposed above the vapor phase V_{V}.

In some embodiments, a heat generating component 25 may be disposed within the interior space such that it is at least partially immersed (up to fully immersed) in the liquid phase V_{L} of the working fluid. That is, while heat generating component 25 is illustrated as being only partially submerged below the upper liquid surface 20, in some embodiments, the heat generating component 25 may be fully disposed below the liquid surface 20. In some embodiments, the heat generating components may include one or more electronic devices, such as computing servers.

In various embodiments, a heat exchanger 30 (e.g., a condenser) may be disposed within the upper volume 15B. Generally, the heat exchanger 30 may be configured such that it is able to condense the vapor phase V_{V} of the working fluid that is generated as a result of the heat that is produced by the heat generating element 25. For example, the heat exchanger 30 may have an external surface that is maintained at a temperature that is lower than the condensation temperature of the vapor phase V_{V} of the working fluid. In this regard, at the heat exchanger 30, a rising vapor phase V_{V} of the working fluid may be condensed back to liquid phase or condensate V_{C} by releasing latent heat to the heat exchanger 30 as the rising vapor phase V_{V} comes into contact with the heat exchanger 30. The resulting condensate V_{C} may then be returned back to the liquid phase V_{L} disposed in the lower volume of 15 A.

In some embodiments, the system 10 may further include a sensing mechanism 100 configured to detect the presence of certain organic contaminants (e.g., hydrocarbon contaminants such as dioctylpthalate, polydimethylsiloxanes, aliphatic and aromatic hydrocarbons, esters, ethers, polyalkylene oxides and various other organic polymers, oligomers, plasticizers, and adjuvants commonly used in the electronics industry) in the working fluids even at very low levels (e.g., 100 ppm or less). In some embodiments, the sensing mechanism 100 may be positioned in the liquid phase V_{L} of the working fluid (or otherwise in fluid communication with the liquid phase V_{L} of the working fluid) and configured to generate a capacitance shift or other electrical response in response to the presence of organic contaminants in the working fluids.

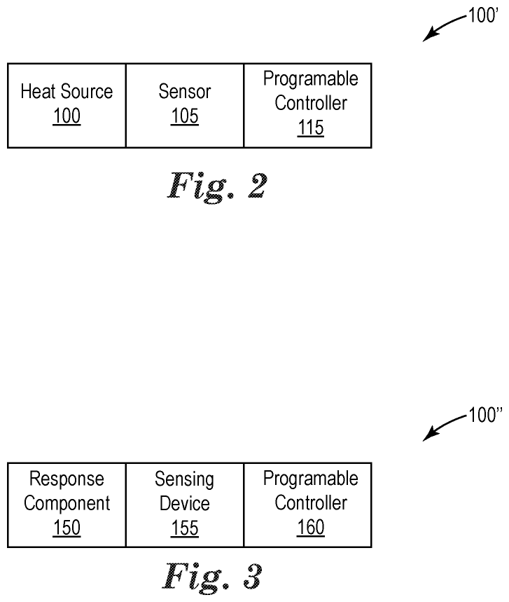

Referring now to FIG. 2, a schematic illustration of a sensing mechanism 100′ in accordance with some embodiments of the present disclosure is illustrated. Generally, the sensing mechanism 100′ may be configured to locally evaporate or distill the working fluid, thereby concentrating the contaminant proximate the sensor and enabling detection by sensors (e.g. capacitive sensor) that would otherwise lack the sensitivity to detect the contaminant at the low concentration in the bulk liquid. In some cases, the contaminant can be made to precipitate from solution onto the sensor (e.g., a capacitance sensor).

As shown, the sensing mechanism 100′ may include a capacitance sensor 105 that is operatively coupled to both a heat source 110 and a programmable controller 115 configured to receive and interpret signals received from the capacitance sensor 105 or initiate a remediation sequence in response to the sensed system parameters.

In some embodiments, the capacitance sensor 105 may include one or more active surfaces, which may be any surface of the sensor 105 that contacts the working fluid such that contaminants may be deposited on the active surface. In this regard, in some embodiments, the capacitance sensor 105 may further include a surface treatment disposed on the active surfaces that operates to promote deposition, retention, or accumulation of organic contaminants on the active surfaces. In some embodiments, suitable surface treatments may include microporous coatings or microstructures like capillaries that promote retention. Suitable treatments might also include chemisorbents or polymers that have an affinity for the contaminant to be detected.

In some embodiments, the capacitance sensor 105 may be configured as a planar sensor, a cylindrical sensor, a parallel plate sensor or an interdigitated electrode sensor, or other similar sensor. In all cases, it is to be appreciated that the presence of the contaminants on the capacitance sensor 105 is reversible (i.e., as the concentration of the contaminants in the thermal management fluid is reduced, the contaminants disposed on the active surfaces may be solubilized/desorbed back into solution).

In some embodiments, the heat source 110 may be any conventional heat source capable of providing heat to the active surfaces (via, for example, a suitable thermal coupling) such that localized boiling of the thermal management fluid on or near the active surfaces may be carried out. Examples of suitable conventional heat sources may include electrically resistive elements such as metallic wires, metallic films on ceramic substrates, or packaged thick film resistors.

In some embodiments, the programmable controller 115 may be in electronic or electrical communication with the capacitance sensor 105 such that it can receive and interpret signals from the capacitance sensor. For example, the programmable controller 115 may be configured to translate signals received from the capacitance sensor 105 (e.g, capacitance shift) into a concentration or relative concentration (i.e., higher or lower than a previous concentration) of certain contaminants in the thermal management fluid. In some embodiments, based on the calculated concentration or relative concentration, the programmable controller 115 may be configured to generate a communication or message for the operator of the system, indicating that a maintenance activity (e.g, filter change) should be carried out. In some embodiments, additionally or alternatively, based on the calculated concentration or relative concentration, the programmable controller 115 may be configured to initiate a remediation sequence. For example, the programmable controller 115 may be further operably coupled to a valve mechanism (not shown) within the system 100′ that routes the thermal management fluid to a contaminant removal flow path (e.g., a pump and filter assembly configured to pull contaminated fluid from the tank and through a filter before routing the thermal management fluid back to the tank).

In some embodiments, the programmable controller 115 may include a processing unit and storage media. A computer program or set of instructions may be coded or otherwise implemented on the processing unit to enable the processing unit to carry out the device operation. In one embodiment, an Internet or World Wide Web (“Web”) browser may be coded into, or otherwise accessed by, the processing unit. The storage media may interface with the processing unit and may store program code and provide storage space for data useful in executing the program code and carrying out functions. The storage media may take the form of, without limitation: a magnetic storage medium; optical storage medium; magneto-optical storage medium; read only memory; random access memory; erasable programmable memory; flash memory; and so on). The features and functionality of the systems and methods of the present disclosure described below may be implemented using hardware, software or a combination of hardware and software. If implemented as software, the software may run on the one or more of the processing units or be stored in the storage media.

Methods of sensing contaminants in a working fluid of an immersion cooling system using the sensing mechanism 100′ may be carried out as follows. The methods may include operating a two-phase immersion cooling system, such as the immersion cooling system 10, described above with respect to FIG. 1. The methods may further include periodically or continuously heating one or more of the active surfaces 120 of the capacitance sensor 105 (via the heat source 100) such that localized boiling of the working fluid on or near the active surfaces may occur. During operation, as discussed above, a concentration of one or more contaminants in the working fluid may increase. As such concentration increases, upon localized boiling of the working fluid at or near the active surfaces, deposition of the one or more contaminants onto the active surface may occur.

In some embodiments, the methods may further include periodically or continuously measuring, via the capacitance sensor 105, the change in capacitance per surface area of the sensor (e.g., from 0 to 64 pF/cm2), and communicating the measured values to the programmable controller 115. The programmable controller may then carryout converting the measured values to a concentration or relative concentration of the one or more contaminants in the working fluid.

In some embodiments, based on the calculated concentration or relative concentration, the methods may include generating or communicating a message for the operator of the system upon the concentration exceeding a predetermined value. For example, the message may indicate that a maintenance activity (e.g, filter change) should be carried out. In some embodiments, additionally or alternatively, based on the calculated concentration or relative concentration, the methods may include the programmable controller 115 initiating a remediation sequence (as discussed above).

In some embodiments, following the maintenance activity, the concentration of the one or more contaminants in the working fluid may decrease. As the concentration decreases, the contaminants present on the active surface may be solubilized/desorbed back into the working fluid. Consequently, the measured capacitance values of the capacitance sensor 105 may return to or approach baseline values.

Referring now to FIG. 3, a schematic illustration of a sensing mechanism 100″ in accordance with some embodiments of the present disclosure is illustrated. As shown, the sensing mechanism 100″ may include a response component 150 that is mechanically coupled to a sensing device 155 that is configured to detect the magnitude of a mechanical response of the response component 150. A programmable controller 160 may be in electronic or electrical communication with the sensing device 155 such that it can receive and interpret signals from the sensing device 155.

In some embodiments, the response component 150 may be any material or device capable of exhibiting a strong mechanical response to even very low concentrations of certain working fluid contaminants in the working fluid. In some embodiments, the response component 150 may include an oleophilic polymeric material such as a silicones, polyethylene terephthalate (PET), polypropylene, polyurethane, polypropylene, polyacrylates, and poly-alpha-olefins. As will be described in further detail in the Examples, it was discovered that certain oleophilic polymeric materials exhibit very strong swelling responses to certain contaminants even at very low concentrations (e.g., 100 ppm or less).

In some embodiments, the sensing device 155 may be any device capable of detecting the magnitude of a mechanical response of the response component 150 and then electronically or electrically communicating the measured values to the programmable controller 160. In some embodiments, the sensing device 155 may include a piezoelectric device such as a quartz crystal microbalance for detecting a change in mass on the quartz crystal surface.

In some embodiments, the programmable controller 160 may be the same as or substantially the same as the programmable controller 115.

Methods of sensing contaminants in a working fluid of an immersion cooling system using the sensing mechanism 100″ may be carried out as follows. The methods may include operating a two-phase immersion cooling system, such as the immersion cooling system 10, described above with respect to FIG. 1. During operation, as discussed above, a concentration of one or more contaminants in the working fluid may increase. As such concentration increases, the response component 150 may exhibit a mechanical response (e.g., swell).

In some embodiments, the methods may further include periodically or continuously measuring, via the sensing device 155, the magnitude of any mechanical response of the response component 150. The programmable controller may then carryout converting the measured values to a concentration or relative concentration of the one or more contaminants in the working fluid.

In some embodiments, based on the calculated concentration or relative concentration, the methods may include generating or communicating a message for the operator of the system upon the concentration exceeding a predetermined value. For example, the message may indicate that a maintenance activity (e.g, filter change) should be carried out. In some embodiments, additionally or alternatively, based on the calculated concentration or relative concentration, the methods may include the programmable controller 160 initiating a remediation sequence (as discussed above).

In some embodiments, following the maintenance activity, the concentration of the one or more contaminants in the working fluid may decrease. As the concentration decreases, the mechanical response of the response component 150 may reverse (e.g, the oleophilic polymeric material may shrink/return to its pre-swell state) as the contaminants present on or in the response component 150 are solubilized/desorbed back into the working fluid. Consequently, the measured values of the sensing device 155 may return to or approach baseline values.

In some embodiments, the contaminants that may be sensed by the sensing mechanisms of the present disclosure include organic contaminants. The organic contaminants may include dioctylpthalate, polydimethylsiloxanes, aliphatic and aromatic hydrocarbons, esters, ethers, polyalkylene oxides and various other organic polymers, oligomers, plasticizers, and adjuvants commonly used in the electronics industry.

While the present disclosure has been described with respect to 2-phase immersion cooling systems, it is to be appreciated that the concepts of the present disclosure may also be employed in single phase immersion cooling systems (i.e., systems in which the temperature of the working fluid does not meet or exceed its boiling point).

In some embodiments, the working fluid may be or include one or more halogenated fluids (e.g., fluorinated or chlorinated). For example, the working fluid may be a fluorinated organic fluid. Suitable fluorinated organic fluids may include hydrofluoroethers, fluoroketones (or perfluoroketones), hydrofluoroolefins, perfluorocarbons (e.g., perfluorohexane), perfluoromethyl morpholine, or combinations thereof.

In some embodiments, in addition to the halogenated fluids, the working fluids may include (individually or in any combination): ethers, alkanes, perfluoroalkenes, alkenes, haloalkenes, perfluorocarbons, perfluorinated tertiary amines, perfluoroethers, cycloalkanes, esters, perfluoroketones, ketones, oxiranes, aromatics, siloxanes, hydrochlorocarbons, hydrochlorofluorocarbons, hydrofluorocarbons, hydrofluoroolefins, hydrochloroolefins, hydrochlorofluoroolefins, hydrofluoroethers, or mixtures thereof based on the total weight of the working fluid; or alkanes, perfluoroalkenes, haloalkenes, perfluorocarbons, perfluorinated tertiary amines, perfluoroethers, cycloalkanes, perfluoroketones, aromatics, siloxanes, hydrochlorocarbons, hydrochlorofluorocarbons, hydrofluorocarbons, hydrofluoroolefins, hydrochlorofluoroolefins, hydrofluoroethers, or mixtures thereof, based on the total weight of the working fluid. Such additional components can be chosen to modify or enhance the properties of a composition for a particular use.

In some embodiments, the working fluids of the present disclosure may have a boiling point during operation (e.g., pressures of between 0.9 atm and 1.1 atm or 0.5 atm and 1.5 atm) of between 30-75° C., or 35-75° C., 40-75° C., or 45-75° C. In some embodiments, the working fluids of the present invention may have a boiling point during operation of greater than 40° C., or greater than 50° C., or greater than 60° C., greater than 70° C., or greater than 75° C.

In some embodiments, the working fluids of the present disclosure may have dielectric constants that are less than 4.0, less than 3.2, less than 2.3, less than 2.2, less than 2.1, less than 2.0, or less than 1.9, as measured in accordance with ASTM D150 at room temperature.

In some embodiments, the working fluids of the present disclosure may be hydrophobic, relatively chemically unreactive, and thermally stable. The working fluids may have a low environmental impact. In this regard, the working fluids of the present disclosure may have a zero, or near zero, ozone depletion potential (ODP) and a global warming potential (GWP, 100 yr ITH) of less than 500, 300, 200, 100 or less than 10.

In some embodiments, the present disclosure may be directed to methods for cooling electronic components. Generally, the methods may include at least partially immersing a heat generating component (e.g., a computer server) in the above discussed working fluid. The method may further include transferring heat from the heat generating component using the above-described working fluid. The method may further include operating any of the above described sensing mechanisms 100/100′/100″ to detect the presence of one or more contaminants in the working fluid.

The operation of the present disclosure will be further described with regard to the following detailed examples. These examples are offered to further illustrate various embodiments and techniques. It should be understood, however, that many variations and modifications may be made while remaining within the scope of the present disclosure.

### Examples

MATERIALS

| Abbreviation | Description and/or Source |
|---|---|
| Electrode 1 | 3-micron monocrystalline silicon interdigitated electrode: |
| | Substrate: 4 mm × 4.3 mm × 0.52 mm P-type monocrystalline silicon with 300 |
| | nm thickness of SiO₂ on the surface of the silicon. Conductor layer 10 nm Cr |
| | and 100 nm Au. Line width 5 μm; line space 3 μm; finger length 1400 μm; |
| | 120 interdigitated pairs (240 fingers). |
| Resistor 1 | MP915-10.0-1% 10 OHM, 15W TO126 resistor, from Caddock Electronics |
| | Inc., Roseburg, Oregon. |
| DP-2216 | A flexible, two-part, room temperature curing epoxy adhesive, DP-2216, |
| | available under the trade designation “3M SCOTCH-WELD EPOXY |
| | ADHESIVE 2216”, from 3M Company, St. Paul, MN. |
| AATA-5G | A two part permanent ceramic adhesive, available under the trade designation |
| | “ARCTIC ALUMINA THERMAL ADHESIVE, AATA-5G”, from Arctic |
| | Silver Incorporated, Visalia, CA. |
| NOVEC 649 | Dodecafluoro-2-methylpentan-3-one, available under the trade designation |
| | “3M NOVEC 649 ENGINEERING FLUID” from 3M Company. |
| DOP | A plasticizer, Dioctyl terephthalate. |

### Fabrication and Experimental Procedures

### Sensor Assembly Fabrication

The sensor was fabricated by bonding the inactive side of the Electrode1 to the heat dissipating region of Resistor1 using AATA-5G. Using DP-2216, this assembly was bonded to a 34 cm brass tube (1147 Round Brass Tubing, 3/16″ OD×0.014″ Wall Thickness, from K&S Precision Metals, Chicago, IL) that was notched such that it extended to cover the solder pads of Electrode1. Polytetrafluoroethylene-clad 28 gage wires, soldered to the solder pads of Electrode 1, were fed through the brass tube. Two additional and similar wires, soldered to the resistor terminals, were extended external to the brass tube.

### Experiment Set-up

The Sensor Assembly was inserted into the opening of a round bottom Pyrex tube, 2-inch (5.1 cm) diameter×12-inch (30.5 cm) length, with the sensor approximately 2 cm from the tube bottom. The resistor leads were connected to a power supply (Model N5652A, from Keysight Technologies, Santa Rosa, CA). Using cable EM-shielded against ambient AC noise, the electrode wires were extended from the brass tube and connected to a potentiostat, coupled with a frequency response analyzer (Princeton Applied Research 273 Potentiostat with a Solartron 1260 Frequency Response Analyzer, Ametek Scientific Research, Berwyn, PA). The brass tube was grounded to the potentiostat.

### Experimental Procedure

Approximately 200 ml of NOVEC 649 was added to the tube. The resistor was powered at 8 V DC. Electrochemical impedance spectroscopy was conducted with Electrode1 using a 5 mV AC excitation signal from a frequency range of 0.01 hz to 100 Khz, with data collected at each decade of frequency. Capacitance at the electrode/film/electrolyte interface was calculated by using a linear extrapolation method available on Scribner Associate's Zplot electrochemistry software. The electrode surface was cleaned between tests by dipping and swirling in high purity acetone for about 30 seconds followed by a rinse with a stream of high purity methanol to remove most of the acetone residue and a subsequent rinse with a stream of high purity ethanol to remove any methanol residue.

### Examples 1 and 2 and Comparative Example 3

Example 1: Approximately 0.5 ml of DOP was added to the pyrex tube and NOVEC 649 with a disposable eye dropper. The heater was run for a period of −16 hours. Following the above experimental procedure, the capacitance at the electrode/film/electrolyte interface when the Sensor Assembly was in NOVEC 649 containing approximately 0.5 ml DOP was measured to be 111 pF.

Example 2: DOP was brushed onto the electrode with a cotton swab. Following the above experimental procedure, the capacitance at the electrode/film/electrolyte interface when the electrode of the Sensor Assembly was brushed with DOP and then placed in NOVEC 649 was measured to be 117 pF.

Comparative Example 3: The capacitance at the electrode/film/electrolyte interface when the Sensor Assembly was in pure NOVEC 649 was measured to be 85.1 pF.

1. A thermal management system comprising:
a housing having an interior space;
a heat-generating component disposed within the interior space;
a working fluid disposed within the interior space such that the heat-generating component contacts a liquid phase of the working fluid; and
a sensing mechanism configured to detect the presence of one or more organic contaminants in the working fluid at concentrations of 100 ppm or less.

2. The thermal management system of claim 1, where the sensing mechanism is configured to locally distill the working fluid such that the one or more organic contaminants are concentrated proximate the sensing mechanism.

3. The thermal management system of claim 2, where the local distillation causes the organic contaminants to precipitate from the working fluid onto a component of the sensing mechanism.

4. The thermal management system of claim 1, wherein the sensing mechanism comprises a capacitance sensor and a heat source operatively coupled to the capacitance sensor.

5. The thermal management system of claim 4, wherein the capacitance sensor comprises one or more active surfaces that contact the working fluid such that one or more of the contaminants can precipitate from the working fluid onto the active surface.

6. The thermal management system of claim 5, further comprising a surface treatment disposed on at least one of the active surfaces that operates to promote deposition, retention, or accumulation of one or more of the organic contaminants on the active surface.

7. The thermal management system of claim 4, wherein the capacitance sensor is configured as a planar sensor, a cylindrical sensor, a parallel plate sensor, or an interdigitated electrode sensor.

8. The thermal management system of claim 1, where the sensing mechanism comprises a response component mechanically coupled to a sensing device configured to atoll detect the magnitude of a mechanical response of the response component.

9. The thermal management system of claim 8, wherein the response component exhibits a mechanical response to the presence of one or more of the organic contaminants at concentrations of as low as 100 ppm or less.

10. The thermal management system of claim 8, wherein the response component comprises an oleophilic polymeric material.

11. The thermal management system of claim 10, wherein the oleophilic polymeric material comprises a silicone, polyethylene terephthalate, polypropylene, polyurethane, polypropylene, polyacrylate, or poly-alpha-olefin.

12. The thermal management system of claim 8, wherein the sensing device comprises a piezoelectric device.

13. The thermal management system of claim 1, wherein the sensing mechanism further comprises a programmable controller that is in electronic communication with the capacitance sensor.

14. The thermal management system of claim 1, wherein the working fluid comprises a fluorinated material.

15. The thermal management system of claim 1, wherein the working fluid has a boiling point at 1 atm of between 30 and 75° C.

16. The thermal management system of claim 1, wherein the working fluid has a dielectric constant less than 2.5.

17. The thermal management system of claim 1, wherein the heat-generating component comprises an electronic device.

18. The thermal management system of claim 1, wherein the electronic device comprises a computing server.

19. The thermal management system of claim 1, wherein the computing server operates at frequency of greater than 3 GHz.

20. The thermal management system of claim 1, wherein the thermal management system further comprises a heat exchanger disposed within the interior space such that upon vaporization of the liquid phase, the vapor phase contacts the heat exchanger.

21-23. (canceled)
